(19) United States
(12) Patent Application Publication
(10) Pub. No.: US 2025/0006423 A1
(43) Pub. Date: Jan. 2, 2025

(54) TRANSFORMER AND RECTIFIER ARRAY FOR HIGH-DENSITY POWER DELIVERY

(71) Applicant: VIRGINIA TECH INTELLECTUAL PROPERTIES, INC., Blacksburg, VA (US)

(72) Inventors: Pranav Raj Prakash, Blacksburg, VA (US); Ahmed Nabih, Blacksburg, VA (US); Qiang Li, Blacksburg, VA (US)

(21) Appl. No.: 18/760,320

(22) Filed: Jul. 1, 2024

Related U.S. Application Data
(60) Provisional application No. 63/511,379, filed on Jun. 30, 2023.

(51) Int. Cl. H01F 38/00; H01F 27/24; H01F 27/28; H05K 1/18

(52) U.S. Cl. CPC H01F 38/00; H01F 27/24; H01F 27/28; H05K 1/181; H01F 2038/006; H05K 2201/10015; H05K 2201/1003; H05K 2201/10166

(57) ABSTRACT

An example transformer cell includes a printed circuit board (PCB) having a plurality of layers and at least two transformers. The at least two transformers include a primary winding implemented in a plurality of primary layers among the plurality of layers, a plurality of secondary windings implemented in a plurality of secondary layers among the plurality of layers, and a core extending through the primary winding and the plurality of secondary windings. The transformer cell further includes a first output capacitor located above a top layer among the plurality of layers and along a first edge of the PCB, a second output capacitor located above the top layer along a second edge of the PCB, the second edge being opposite the first edge. The transformer cell additionally includes one or more switching devices located between the first and the second output capacitors.

### BACKGROUND

Many electronic devices and systems rely upon power at a well-regulated, constant, and well-defined voltage for proper operation. In that context, power conversion devices and systems are relied upon to convert electric power or energy from one form to another. A power converter is an electrical or electro-mechanical device or system for converting electric power or energy from one form to another. As examples, power converters can convert alternating current (AC) power into direct current (DC) power, convert DC power to AC power, provide a DC to DC conversion, provide an AC to AC conversion, change or vary the characteristics (e.g., the voltage rating, current rating, frequency, etc.) of power, or offer other forms of power conversion. A power converter can be as simple as a transformer, but many power converters have more complicated designs and are tailored for a variety of applications and operating specifications.

Many applications rely upon high-efficiency DC-DC converters that provide isolation to the load. Although many topologies are good candidates for this application, resonant converters can be desirable due to their ability to achieve soft-switching for the primary and secondary devices, thereby enabling the frequencies to be increased, resulting in higher power densities.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 depicts an example circuit schematic of an example transformer cell according to one or more embodiments of the present disclosure.

FIG. 2 depicts a perspective view of the transformer cell shown in FIG. 1 according to one or more embodiments of the present disclosure.

FIG. 3 depicts the transformer cell shown in FIG. 1 implemented in various layers of a printed circuit board (PCB) according to one or more embodiments of the present disclosure.

FIG. 4 depicts a circuit schematic of the transformer cell shown in FIG. 1 including various switching nodes and output voltage nodes, according to one or more embodiments of the present disclosure.

FIG. 5A depicts a top-down view of a winding turn of a first secondary winding of the transformer cell shown in FIG. 1 according to one or more embodiments of the present disclosure.

FIG. 5B depicts a top-down view of a winding turn of a second secondary winding of the transformer cell shown in FIG. 1 according to one or more embodiments of the present disclosure.

FIG. 6 depicts a top-down view of a top layer including various switching devices of the transformer cell shown in FIG. 1, according to one or more embodiments of the present disclosure.

FIG. 7A depicts the current in one half-cycle through the first secondary winding of the transformer cell shown in FIG. 1 according to one or more embodiments of the present disclosure.

FIG. 7B depicts the current in the other half-cycle, as compared to the half-cycle shown in FIG. 7A, through the second secondary winding of the transformer cell shown in FIG. 1, according to one or more embodiments of the present disclosure.

FIG. 8 depicts a circuit schematic of an example matrix transformer including multiple unit cells according to one or more embodiments of the present disclosure.

FIG. 9 depicts a perspective view of the matrix transformer shown in FIG. 8, according to one or more embodiments of the present disclosure.

FIG. 10 depicts a perspective view of a primary winding of the matrix transformer shown in FIG. 8, according to one or more embodiments of the present disclosure.

FIG. 11 depicts a perspective view of a first secondary winding and a second secondary winding of the matrix transformer shown in FIG. 8, according to one or more embodiments of the present disclosure.

FIG. 12 depicts a circuit schematic of a transformer cell including center-tap rectifiers with parallel switching devices according to one or more embodiments of the present disclosure.

FIG. 13 depicts a perspective view of the transformer cell shown in FIG. 12, according to one or more embodiments of the present disclosure.

FIG. 14 depicts a circuit schematic of a transformer cell including full-bridge rectifiers according to one or more embodiments of the present disclosure.

FIG. 15 depicts a perspective view of the transformer cell shown in FIG. 14, according to one or more embodiments of the present disclosure.

FIG. 16 depicts a cell arrangement of the matrix transformer shown in FIG. 8 according to one or more embodiments of the present disclosure.

FIG. 17 depicts a cell array arrangement of the matrix transformer shown in FIG. 8 according to one or more embodiments of the present disclosure.

FIG. 18 depicts a schematic of an example two-stage power delivery system according to one or more embodiments of the present disclosure.

FIG. 19 depicts a schematic of an example two-stage power delivery system that improves upon various features of the two-stage power delivery system shown in FIG. 18, according to one or more embodiments of the present disclosure.

FIG. 20 depicts a schematic of an example two-stage power delivery system that improves upon various features of the two-stage power delivery system shown in FIG. 18, according to one or more embodiments of the present disclosure.

FIG. 21 depicts a schematic of an example two-stage power delivery system that improves upon various features of the two-stage power delivery system shown in FIG. 18, according to one or more embodiments of the present disclosure.

### DETAILED DESCRIPTION

Power conversion devices and systems are relied upon to convert electric power or energy from one form to another. A power converter is an electrical or electro-mechanical device or system for converting electric power or energy from one form to another. As examples, power converters can convert alternating current (AC) power into direct current (DC) power, convert DC power to AC power, provide a DC to DC conversion, provide an AC to AC conversion, change or vary the characteristics (e.g., the voltage rating, current rating, frequency, etc.) of power, or offer other forms of power conversion. A power converter can be as simple as a transformer, but many power converters have more complicated designs and are tailored for a variety of applications and operating specifications.

A range of isolated and non-isolated power converters are known. In isolated high power converters, especially those requiring high voltage step-down ratios, the secondary-side current is often too high for a single transformer to handle without incurring high losses. It is also common to have multiple secondary-side rectifiers (SRs) in a paralleled configuration in such high power converters with high voltage step-down ratios.

Among various industrial applications, power management solutions for datacenters and telecom applications are among those gaining the most attention. By 2030, the total electricity demand of information and communication technology is estimated to accelerate to reach around 20% of projected energy demand, and the datacenters, especially in the form of hyper-scale datacenters, will likely be responsible for 40% of that projection. This boom in energy demand led to an overhaul of the datacenter power architecture, with the traditional architecture employing 12V as the bus voltage to server racks being replaced by 48V to reduce power delivery network (PDN) losses. The reduction in up to 30% in electrical conversion losses has led to many top tech companies to transition to the 48V bus architecture.

Central processing units (CPUs) and graphical processing units (GPUs) are the two mainstream options for general purpose computing. Data scientists striving for super charged productivity, sped-up workflows, and unlocking the full potential of artificial intelligence (AI) and machine learning (ML) are therefore seeking ultra-powerful GPUs that will accelerate the pace of innovation. The increase in power also inevitably results in the increase in die size, albeit not as steeply. Therefore, due to their higher power requirements, GPUs pose a greater challenge for power management systems than CPUs.

In power converters, a two-stage power delivery system is typically implemented to supply the GPU with the required high currents (>500 A) at ultra-low voltages (0.8V-1V) from the 48V DC entering the server rack. The commonly implemented power architecture has the first stage as an unregulated bus converter that steps down the 48V to an intermediate bus voltage (IBV) with high efficiency. The second stage consists of voltage regulators (VRs) that provide precisely regulated voltages and frequency to the various GPU domains, while dealing with their rigorous transient requirements.

Existing GPU architectures can utilize the popular 12V IBV, with the first stage 48V/12V intermediate bus converter (IBC), followed by the second stage 12V/1V multi-phase buck VRs. However, due to the large inductor sizes of these 12V/1V VRs, the second stage occupies a majority of the real-estate on the board. Based on current trends, the current architecture is inadequate to handle the increasing power requirements, while having lesser real-estate on the board due to the larger GPU die. To address the dearth of real-estate for the high-current VRs and GPUs in the future, a paradigm shift in the power delivery architecture is needed to boost the power delivery output power and power density while maintaining high efficiency. This can be achieved with the vertical power delivery (VPD) architecture. In a VPD architecture, the second stage VR is moved to the bottom of the GPU card directly underneath the GPU chip, so that the high current at 1V reaches the GPU with minimum PDN losses. However, to achieve this, the VRs must satisfy the strict footprint and profile constraints, which are mainly determined by the switching frequency and the IBV.

A lower IBV results in higher duty-cycle operation, resulting in better efficiency. This further allows the frequency to be pushed higher, resulting in smaller magnetics and fewer output capacitors. Although reducing the IBV results in lower efficiency and power density for the first stage IBC, the efficiency of the second stage VRs increases significantly, resulting in an overall increase in system efficiency. However, a lower IBV also increases the PDN losses from the first to the second stage, thereby affecting the overall system efficiency. Therefore, selecting the optimal IBV is crucial to maximize power delivery.

In the context outlined above, various embodiments of the present disclosure relate to power converters with high density transformer cells. In one example, a transformer cell includes a printed circuit board (PCB) including a plurality of layers and at least two transformers. The at least two transformers include a primary winding implemented in a plurality of primary layers among the plurality of layers, a plurality of secondary windings implemented in a plurality of secondary layers among the plurality of layers, and a core including a first core half and a second core half, where the core extends through the primary winding and the plurality of secondary windings. The transformer cell further includes a first output capacitor electrically connected to the plurality of secondary windings and located above a top layer and/or below a bottom layer among the plurality of layers and along a first edge of the PCB. The transformer cell further includes a second output capacitor electrically connected to the plurality of secondary windings and located above the top layer and/or below the bottom layer and along a second edge of the PCB, where the second edge is opposite the first edge. Additionally, the transformer cell includes one or more switching devices electrically connected to the first output capacitor and the second output capacitor, where the one or more switching devices are located between the first output capacitor and the second output capacitor.

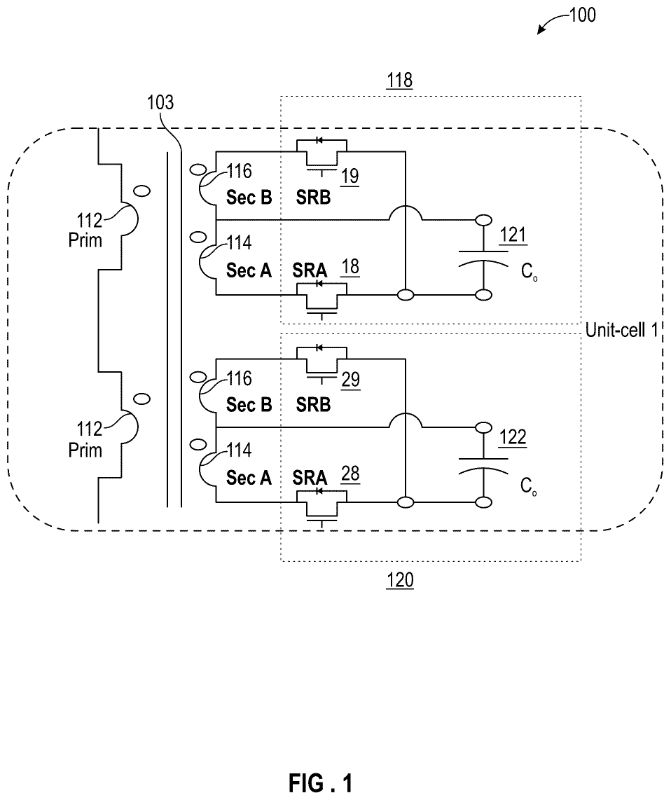

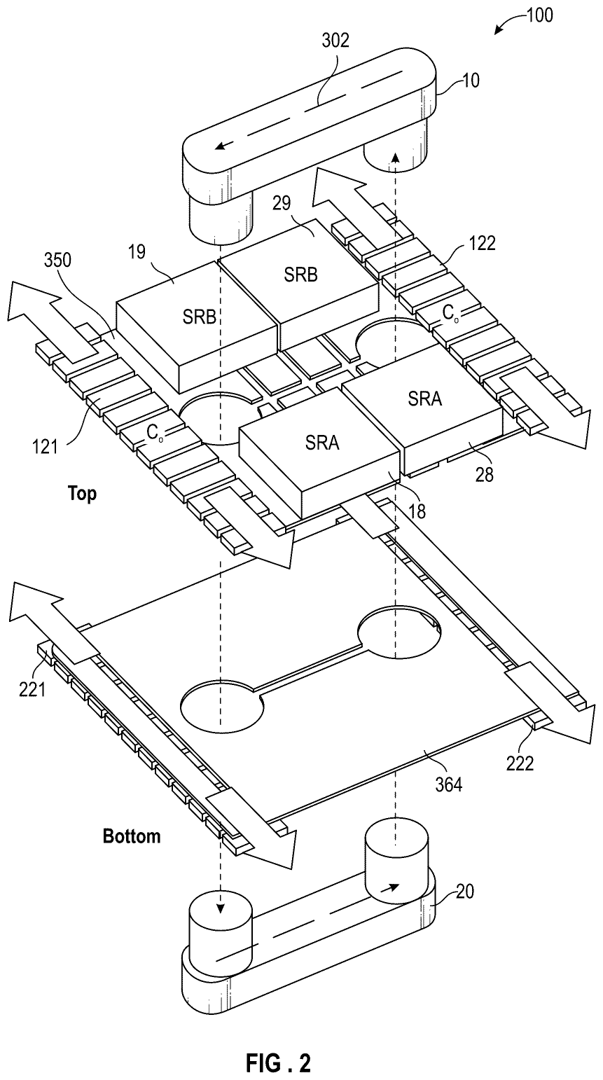

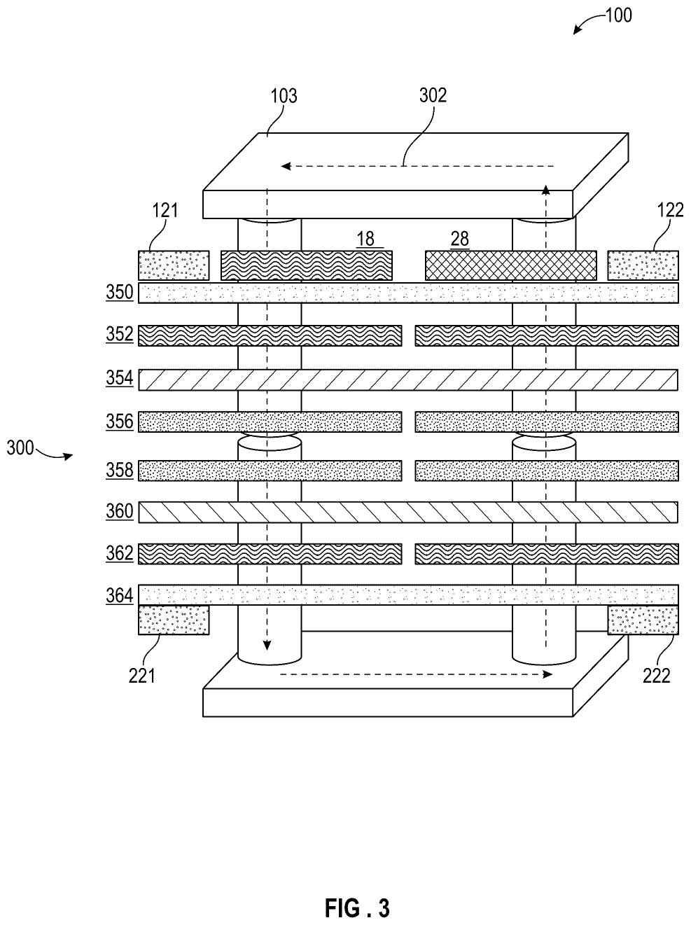

Referring now to the drawings, FIG. 1 depicts a circuit schematic of an example transformer cell 100, FIG. 2 depicts a perspective view of the transformer cell 100, and FIG. 3 depicts the transformer cell 100 implemented in various layers of a PCB, according to one or more embodiments of the present disclosure. FIGS. 1-3 are not exhaustively illustrated, meaning that other components not shown in FIGS. 1-3 can be included or relied upon in some cases. Similarly, one or more components shown in FIGS. 1-3 can be omitted in some cases. Additionally, FIGS. 1-3 are not necessarily drawn to any particular scale or size. The transformer cell 100 is a unit-cell of a matrix transformer and can include a combination of one or more primary and secondary transformer windings, switching devices such as secondary rectifiers (SRs), and filter or output capacitors. A unit-cell generally includes at least two elemental transformers integrated with a single UU/UI core. The transformer cell 100 is implemented in a printed circuit board (PCB), such as shown in FIG. 3, that includes a plurality of layers 300. The transformer cell 100 further includes two transformers defined by a primary winding 112 implemented in a plurality of primary layers among the plurality of layers 300, a first secondary winding 114 implemented in a first plurality of secondary layers among the plurality of layers 300, a second secondary winding 116 implemented in a second plurality of secondary layers among the plurality of layers 300, and a magnetic core 103 that extends through the primary winding 114, the first secondary winding 114, and the second secondary winding 116. The magnetic core 103 includes a first core half 10 and a second core half 20 which can be integrated to form a single UU/UI core. The magnetic core 103 can facilitate a magnetic flux direction 302 as depicted in FIGS. 2 and 3. The transformer cell 100 further includes a first SR system 118 including switching devices 18, 19, and a first output capacitor 121 and a second SR system 120 including switching devices 28, 29, and a second output capacitor 122. The switching devices 18, 19, 28, and 29 can be embodied as diodes, metal-oxide-semiconductor field-effect transistors (MOSFETs), or high electron mobility transistors (HEMTs), among other switching devices.

The first output capacitor 121 is electrically connected to the first and the second plurality of secondary windings 114 and 116 and is located above a top layer 350 among the plurality of layers 300 and along a first edge of the PCB. The second output capacitor 122 is electrically connected to the first and the second plurality of secondary windings 114 and 116 and is located above the top layer 350 and along a second edge of the PCB, where the second edge is opposite the first edge. The switching devices 18 and 19 of the first SR system 118 are electrically connected to the first output capacitor 121, and the switching devices 28 and 29 of the second SR system 118 are electrically connected to the second output capacitor 122. The switching devices 18 and 19 of the first SR system 118 and the switching devices 28 and 29 of the second SR system 120 are located between the first output capacitor 121 and the second output capacitor 122 at or above the top layer 350 of the PCB.

In some embodiments, the transformer cell 100 can include a third output capacitor 221 electrically connected to the first and the second plurality of secondary windings 114 and 116 and a fourth output capacitor 222 electrically connected to the first and the second plurality of secondary windings 114 and 116. The third output capacitor 221 can be located below a bottom layer 364 of the plurality of layers 300 and along the first edge of the PCB, similar to the positioning of the first output capacitor 121. Additionally, the third output capacitor 221 and the first output capacitor 121 are symmetrically aligned. The fourth output capacitor 222 can be located below the bottom layer 364 and along the second edge of the PCB, similar to the positioning of the second output capacitor 122. Additionally, the fourth output capacitor 222 and the second output capacitor 122 are symmetrically aligned.

The transformer cell 100 can be configured in an array of multiple transformer cells (e.g., multiple transformer cells 100 that are arranged in an array of rows and/or columns) depending on the IBV that is needed for an overall power conversion system. For example, if a larger step-down ratio is required for converting a bus voltage to the required IBV for delivery to a second stage VR system and to a load, more transformer cells 100 can be arranged in an array. Further description regarding arrangement into an array of multiple transformer cells is provided below in the later paragraphs.

Referring to FIG. 3 and as discussed above, the transformer cell 100 is implemented in various layers of the plurality of layers 300. In a non-liming example, the plurality of layers 300 includes 8 layers including a top layer 350, a bottom layer 364, and intermediate layers 352, 354, 356, 358, 360, and 362 for implementing one or more winding turns of the primary winding 112, the first secondary winding 114, and the second secondary winding 116. For example, the intermediate layers 354 and 360 correspond to separate winding turns of the primary winding 112, the intermediate layers 352 and 362 correspond to separate winding turns of the first secondary winding 114, and the intermediate layers 356 and 358 correspond to separate winding turns of the second secondary winding 116, all of which can be sequentially stacked to maximize primary-secondary current interleaving, thereby minimizing the magnetomotive force (MMF) between each of the layers 350, 352, 354, 356, 358, 360, 362, and 364. The intermediate layers 354 and 360 (corresponding to the separate winding turns of the primary winding 112) can be connected in series or parallel through vias or interconnects, the intermediate layers 352 and 362 (corresponding to the separate winding turns of the first secondary winding 114) can be connected in series or parallel through vias or interconnects, and the intermediate layers 356 and 358 (corresponding to the separate winding turns of the second secondary winding 116) can be connected in series or parallel through vias or interconnects.

However, FIG. 3 is shown as an example of many different layer stack-ups that can be implemented for the transformer cell 100. In some embodiments, the transformer cell 100 can be implemented in a 4-layer PCB, a 14-layer PCB, or other layer PCBs (e.g., the plurality of layers 300 can include 4 layers, 14 layers, etc.). For example, depending on the step-down ratio required from the bus voltage to the IBV and depending on the application or requirements of the second stage VR or the load, an adequate layer stack-up of the PCB can be implemented for the transformer cell 100.

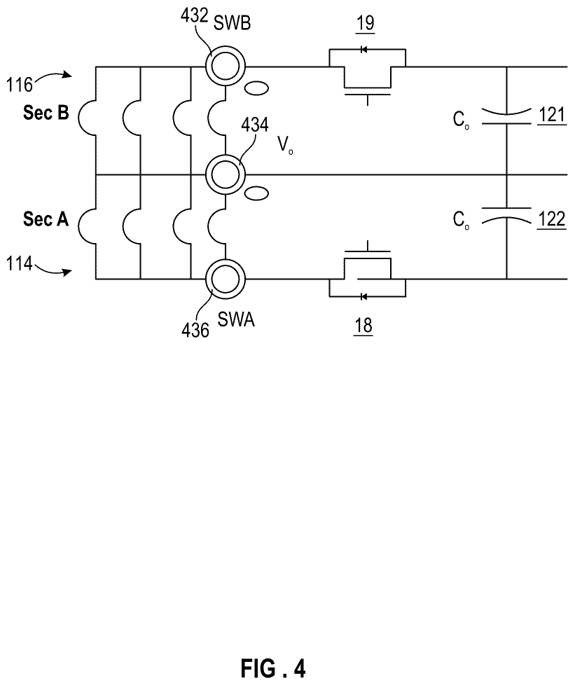

FIG. 4 depicts a circuit schematic of the transformer secondary windings and center-tap rectification system (parts of the transformer cell 100) including various switching nodes and output voltage nodes, according to one or more embodiments of the present disclosure. As discussed above, the first secondary winding 114 and the second secondary winding can each include a plurality of winding turns implemented in different layers among the plurality of layers 300. Each winding turn of the first secondary winding 114 can be electrically connected to the switching devices 18 and/or 28 via a first switching node 436, and each winding turn of the second secondary winding 116 can be electrically connected to the switching devices 19 and/or 29 via a second switching node 432. For example, each winding turn of the first secondary winding 114 can include multiple switching nodes 436 for electrical connection to the switching devices 18 and/or 28, and each winding turn of the second secondary winding 116 can include multiple switching nodes 432 for electrical connection to the switching devices 19 and/or 29.

Similarly, each winding turn of the first secondary winding 114 and the second secondary winding 116 can be electrically connected to the output capacitors 121 and/or 122 via an output voltage node 434. For example, each winding turn of the first secondary winding 114 and the second secondary winding 116 can include multiple output voltage nodes 434 for electrical connection to the output capacitors 121 and/or 122.

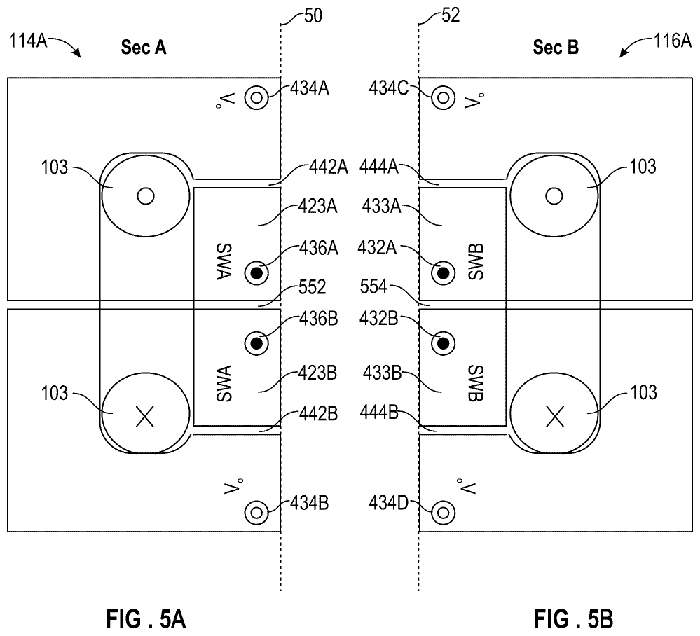

FIG. 5A depicts a top-down view of a winding turn 114A of the first secondary winding 114, and FIG. 5B depicts a top-down view of a winding turn 116A of the second secondary winding 116, according to one or more embodiments of the present disclosure. The winding turns 114A and 116A are representative of each winding turn of the first secondary winding 114 and the second secondary winding 116. Although FIGS. 5A and 5B illustrate a side-by-side view of the winding turn 114A and the winding turn 116A, it should be noted that each winding turn of the first secondary winding 114 and the second secondary winding 116 is symmetrically aligned and sequentially stacked but in mirror or reverse configurations with one another respective to the core 103.

Referring to FIG. 5A, switching nodes 436A and 436B are located centrally away from the core 103 in a first direction toward a first edge 50 of the winding turn 114A. The switching nodes 436A and 436B are also separated by an air gap 552. Preferably, the switching nodes 436A and 436B are located at or substantially near the first edge 50 so that switching areas 423A and 423B that enclose or surround the switching nodes 436A and 436B, respectively, are confined to areas defined by air gaps 442, the air gap 552, and the core 103. For example, the switching area 423A is confined to the area defined by air gap 442A, the air gap 552, and the core 103, and the switching area 423B is confined to the area defined by air gap 442B, the air gap 552, and the core 103. The rotation of the switching nodes 436A and 436B to the locations described above, as compared to existing techniques, enables the switching devices 18 and 28 to be positioned beside the core 103 and symmetrically aligned with the switching areas 423A and 423B. Particularly, the switching devices 18 and 28 can be positioned directly above the switching areas 423A and 423B at or above the top layer 350 as illustrated in FIGS. 2 and 3.

The winding turn 114A includes output voltage nodes 434A and 434B which are also located peripherally away from the core 103 in the first direction toward the first edge 50. The output voltage node 434A is separated from the switching node 436A by the air gap 442A. The output voltage node 434B is separated from the switching node 436B by the air gap 442B. The switching nodes 436A and 436B are positioned between the output voltage nodes 434A and 434B. The first secondary winding 114 can be configured to provide an output voltage to the output capacitors 121, 122, 221, and/or 222 via the output voltage nodes 434A and 434B.

Referring to FIG. 5B, switching nodes 432A and 432B are located centrally away from the core 103 in a second direction toward a second edge 52 of the winding turn 116A. As discussed above, each winding turn of the first secondary winding 114 and the second secondary winding 116 are symmetrically aligned and sequentially stacked. Thus, the first edge 50 is opposite the second edge 52 in the layer stack of the plurality of layers 300. The switching nodes 432A and 432B are separated by an air gap 554. Preferably, the switching nodes 432A and 432B are located at or substantially near the second edge 52 so that switching areas 433A and 433B that enclose or surround the switching nodes 432A and 432B, respectively, are confined to areas defined by air gaps 444, the air gap 554, and the core 103. For example, the switching area 433A is confined to the area defined by air gap 444A, the air gap 554, and the core 103, and the switching area 433B is confined to the area defined by air gap 444B, the air gap 554, and the core 103. The rotation of the switching nodes 432A and 432B to the locations described above, as compared to existing techniques, enables the switching devices 19 and 29 to be positioned beside the core 103 and symmetrically aligned with the switching areas 433A and 433B. Particularly, the switching devices 19 and 29 can be positioned directly above the switching areas 433A and 433B at or above the top layer 350 as illustrated in FIGS. 2 and 3.

The winding turn 116A includes output voltage nodes 434C and 434D which are also located peripherally away from the core 103 in the second direction toward the second edge 52. The output voltage node 434C is separated from the switching node 432A by the air gap 444A. The output voltage node 434D is separated from the switching node 432B by the air gap 444B. The switching nodes 432A and 432B are positioned between the output voltage nodes 434C and 434D. The first secondary winding 116 can be configured to provide an output voltage to the output capacitors 121, 122, 221, and/or 222 via the output voltage nodes 434C and 434D.

In some embodiments, a winding turn can include a combination of windings of the first secondary winding 114 and the second secondary winding 116. For example, although the winding turn 114A is described to correspond to a winding turn of the first secondary winding 114 and includes the switching nodes 436A and 436B, the winding turn 114A can include a winding of the first secondary winding 114 in an upper portion and a winding of the second secondary winding 116 in a lower portion. In other words, the winding turn 114A can include, instead of the switching node 436B in the lower portion, the switching node 432 (e.g., the switching node 432A, 432B, etc.) in the lower portion, or vice-versa. The above-mentioned description is also applicable to the winding turn 116A as well.

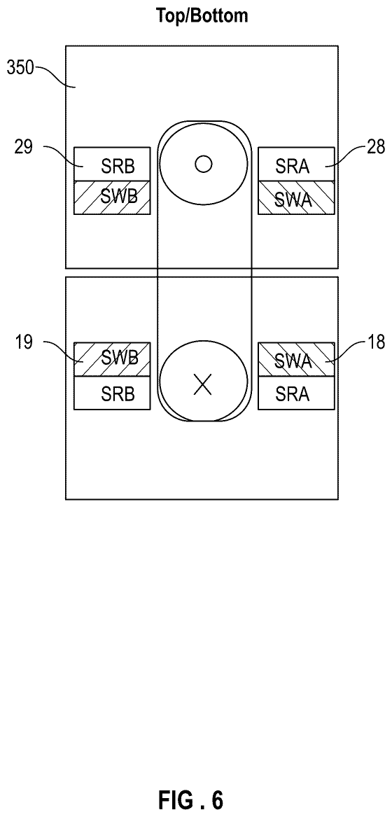

FIG. 6 depicts a top-down view of the top layer 350 including the switching devices 18, 28, 19, and 29, according to one or more embodiments of the present disclosure. As discussed above, the switching devices 18 and 28 can be configured to be electrically connected to the switching nodes 436A and 436B (e.g., the switching device 18 can be configured to be electrically connected to the switching node 436B and the switching device 28 can be configured to be electrically connected to the switching node 436A), and the switching devices 19 and 29 can be configured to be electrically connected to the switching nodes 432A and 432B (e.g., the switching device 19 can be configured to be electrically connected to the switching node 432B and the switching device 29 can be configured to be electrically connected to the switching node 432A. The location of the switching nodes 436A and 436B enables the switching device 18 to be positioned directly above the switching area 423B and the switching device 28 to be positioned directly above the switching area 423A, at or above the top layer 350. The location of the switching nodes 432A and 432B enables the switching device 19 to be positioned directly above the switching area 433B and the switching device 29 to be positioned directly above the switching area 433A, at or above the top layer 350. The above-described layout of the switching nodes 436A and 436B and the output voltage nodes 434A and 434B for the winding turn 114A and the switching nodes 432A and 432B and the output voltage nodes 434C and 434D enable the transformer cell 100 to accommodate the switching devices 18, 28, 19, and 29, and the output capacitors 121 and 122 all above or at the top layer 350 in a dense configuration. It should be noted that FIG. 6 is provided as an example view of the top layer 350. The above description is also applicable to the bottom layer 364 (which can have an identical top-down view as the top layer 350). For example, the bottom layer 364 can also accommodate additional output capacitors and switching devices as will be discussed in the following paragraphs.

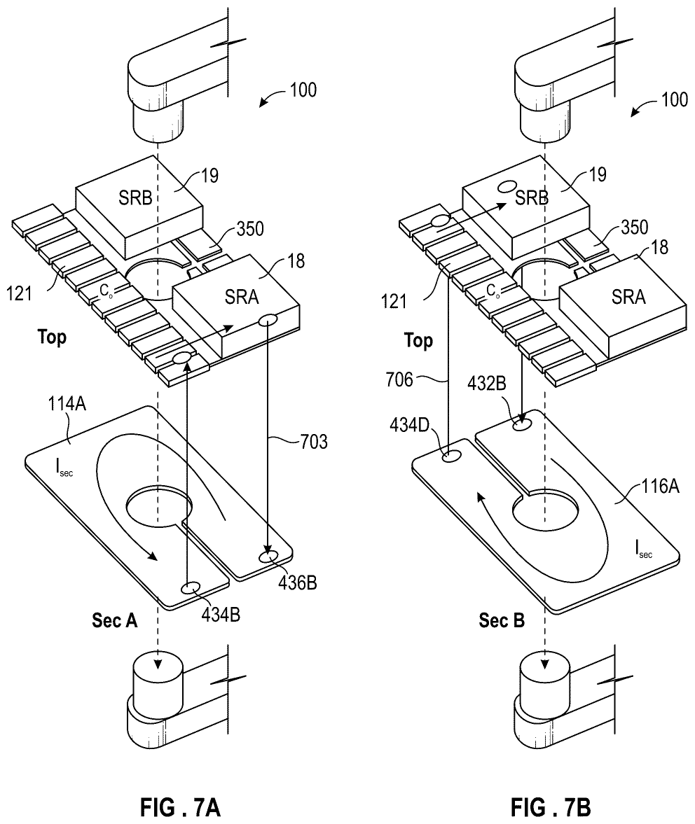

FIG. 7A depicts the secondary current flow in a switching half-cycle through the first secondary winding 114, and FIG. 7B depicts the secondary current flow in a switching current half-cycle through the second secondary winding 116, according to one or more embodiments of the present disclosure. Referring to FIG. 7A, a half-cycle current 703 can flow in the direction as depicted. The half-cycle current 703 is confined to a small loop area, minimizing power loss and achieving higher power density without sacrificing efficiency for the transformer cell 100. Referring to FIG. 7B, a half-cycle current 706 can flow in the direction as depicted. Similar to the half-cycle current 703, the half-cycle current 706 is confined to a small loop area, minimizing power loss and achieving higher power density without sacrificing efficiency for the transformer cell 100.

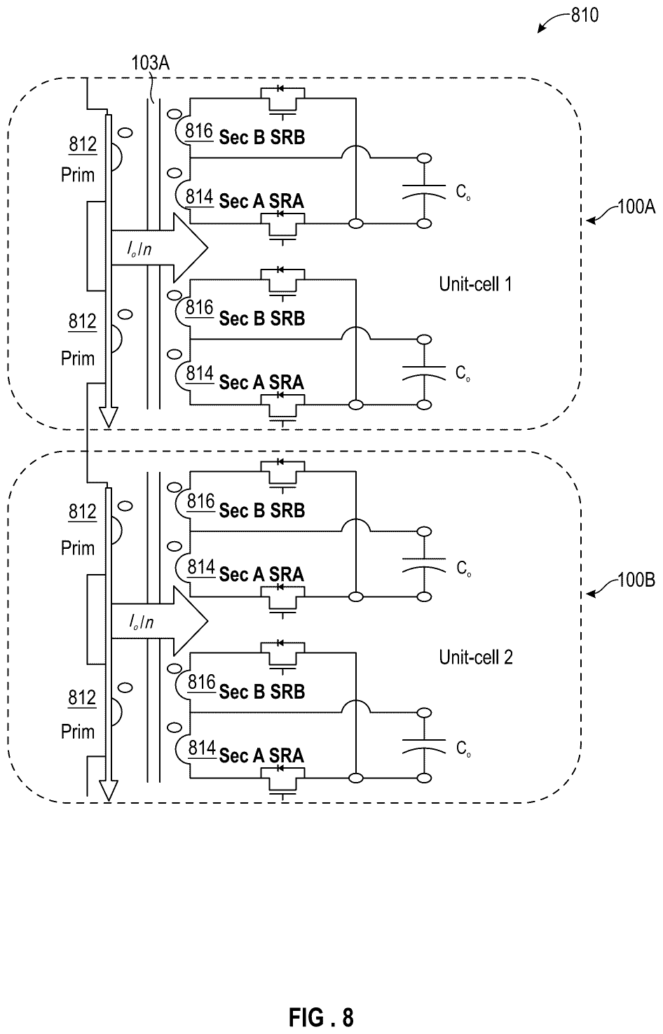

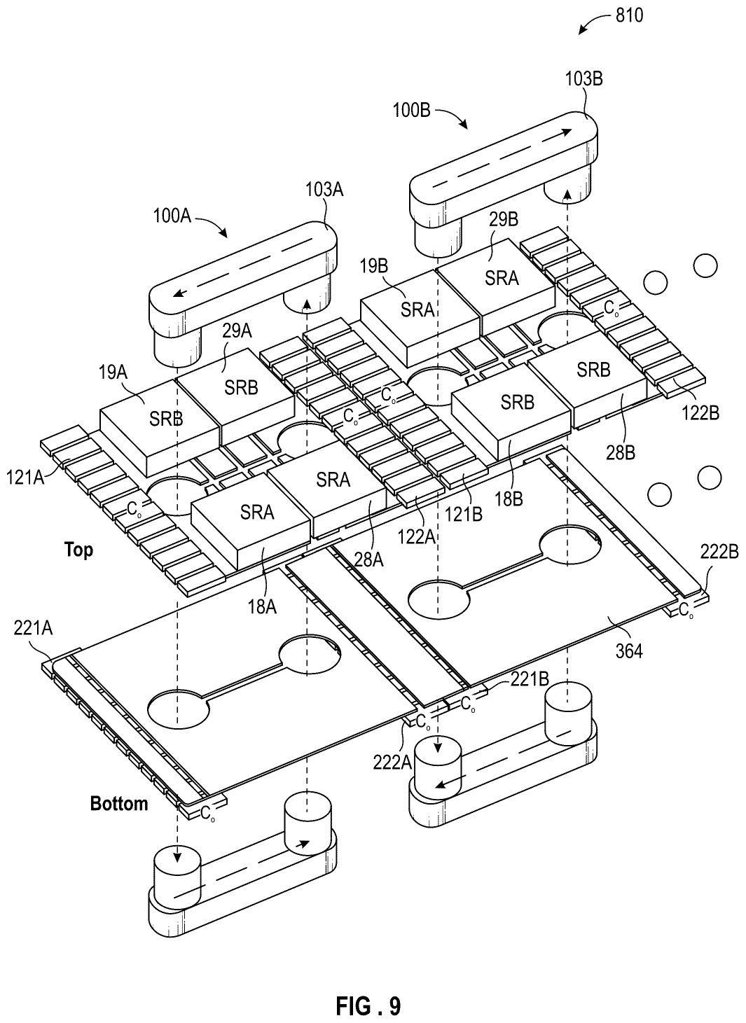

FIG. 8 depicts a circuit schematic of an example matrix transformer 810 including multiple transformer cells, and FIG. 9 depicts a perspective view of the unit-cell arrangement of the matrix transformer 810, according to one or more embodiments of the present disclosure. FIGS. 8 and 9 are not exhaustively illustrated, meaning that other components not shown in FIGS. 8 and 9 can be included or relied upon in some cases. Similarly, one or more components shown in FIGS. 8 and 9 can be omitted in some cases. Additionally, FIGS. 8 and 9 are not necessarily drawn to any particular scale or size. Referring to FIG. 8, the matrix transformer 810 can be comprised of multiple transformer cells 100 that are connected in series. For example, the matrix transformer 810 can include one or more transformer cells 100 (e.g., transformer cells 100A and/or 100B) that are each connected in series with one another. The matrix transformer 810 can include as many transformer cells 100 as needed for providing a desired IBV voltage to a second stage VR system or a load. For example, “Io” refers to the total output current and “n” refers to the number of elemental transformers. The matrix transformer 810 can include multiple transformer cells 100 arranged linearly in a row (as depicted in FIGS. 8 and 9) or can include multiple transformer cells 100 arranged in a l×m array. The matrix transformer 810 includes a primary winding 812, which includes multiple winding turns that are implemented in various layers of a plurality of layers of a PCB. Similar to an individual transformer cell 100 which can be implemented among the plurality of layers 300, the matrix transformer 810 can also be implemented among the plurality of layers 300. In this context, the primary winding 812 can be implemented in plurality of primary layers among the plurality of layers 300 of the PCB shown in FIG. 3. The primary winding 812 can be configured to direct a semi-serpentine current flow based on a plurality of air gaps structurally integrated in the primary winding which will be discussed in the following paragraphs.

The matrix transformer 810 further includes a first secondary winding 814 implemented in a first plurality of secondary layers among the plurality of layers 300 and a second secondary winding 816 implemented in a second plurality of secondary layers among the plurality of layers 300. The first secondary winding 814 can be formed from physically merging the first secondary windings of the transformer cells 100A and 100B, and the second secondary winding 816 can be formed from physically merging the second secondary windings of the transformer cells 100A and 100B. The merging of the first secondary windings and the second secondary windings of the transformer cells 100A and 100B can provide one or more merged output voltage nodes between the transformer cells 100A and 100B as will be discussed in the following paragraphs. Each transformer cell 100A, 100B, and so forth includes a core 103A, 103B, and so forth. Each of the cores 103A and 103B extends through the primary winding 812 and the first secondary winding 814 and the second secondary winding 816. Each transformer cell (e.g., 100A, 100B, and so forth) of the matrix transformer 810 includes a SR system (e.g., the SR systems 120, 121, etc.) including one or more SRs and output capacitors as depicted in FIGS. 8 and 9 in a similar configuration as described with respect to FIG. 2 for the transformer cell 100. For example, the transformer cell 100A can include switching transistors 18A, 19A, 28A, and 29A and output capacitors 121A, 122A, 221A, and 222A. The transformer cell 100B can include switching transistors 18B, 19B, 28B, and 29B and output capacitors 121B, 122B, 221B, and 222B.

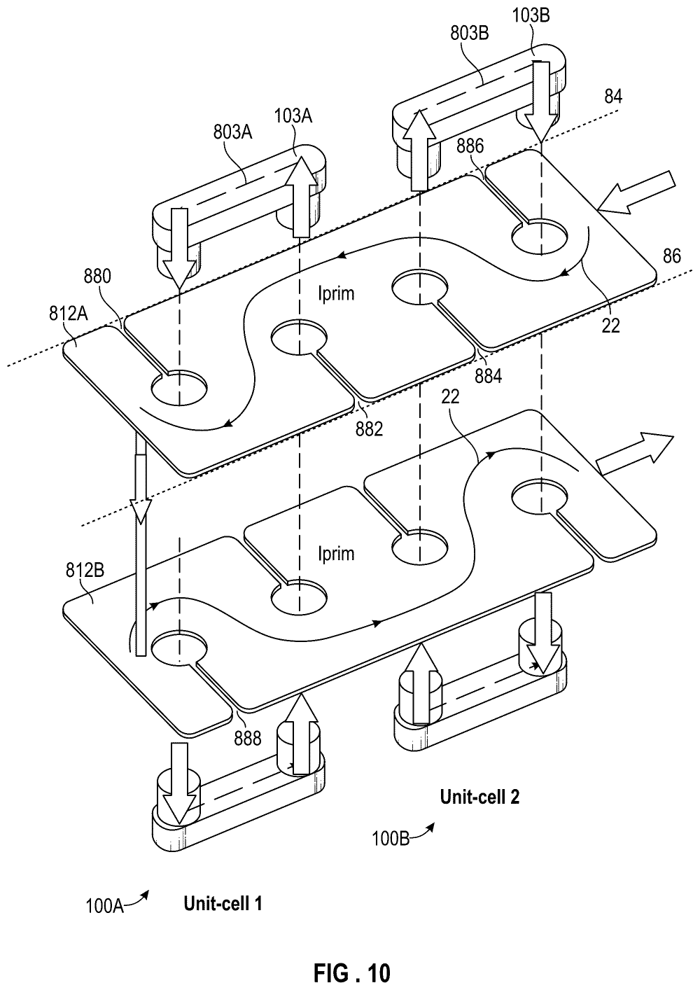

FIG. 10 depicts a perspective view of the primary winding 812 according to one or more embodiments of the present disclosure. As discussed above, the primary winding 812 can include multiple winding turns with each winding turn can be implemented in a separate primary layer among the plurality of layers 300. For example, the primary winding 812 includes a first winding turn 812A and a second winding turn 812B of which can be electrically connected in series. The winding turn 812A can be implemented in the intermediate layer 354, and the winding turn 812B can be implemented in the intermediate layer 360, for example. Furthermore, multiple such intermediate layers can be connected in parallel to distribute the high primary current. The primary winding 812 can be configured to generate a current based on a direct current (DC) voltage (e.g., bus voltage) received from a DC power source. For example, the winding turn 812A can be configured to direct a current 22 having a semi-serpentine current flow. A direction of the semi-serpentine current flow can include a partially twisted or curved current flow defined by a positioning of air gaps 880, 882, 884, and 886 that are structurally integrated in the winding turn 812A. The air gaps 882 and 884 are central air gaps that extend away from the cores 103A and 103B toward a first edge 86 of the primary winding 812. The air gaps 880 and 886 are outer air gaps that extend away from the cores 103A and 103B toward a second edge 84 of the primary winding 812, where the second edge 84 is opposite the first edge 86. The air gaps 882 and 884 both extending toward the first edge 86 (as opposed to alternatingly extending in opposite directions) enable the current 22 to not twist in the central portions of the winding turn 812A as depicted, which is an important distinction compared to conventional techniques for maintaining the semi-serpentine current flow.

The winding turn 812B can be configured to direct the current 22 received from the winding turn 812A in the direction depicted. The current 22 maintains the semi-serpentine current flow in the winding turn 812B in an inverse or reverse twisting pattern and/or direction. For example, the winding turn 812B integrates similar air gaps as the first winding turn 812A but in a mirror or reverse configuration (e.g., central air gaps for the winding turn 812B extend away from the cores 103A and 103B toward the second edge 84 instead of the first edge 86, and outer air gaps for the winding turn 812B extend away from the cores 103A and 103B toward the first edge 86 instead of the second edge 84, etc.). The structure of the primary winding 812 as described above facilitates magnetic flux directions 803A and 803B in the cores 103A and 103B, respectively. For example, the semi-serpentine current flow described above can cause the magnetic flux direction 803A in the core 103A to be inversed from the magnetic flux direction 803B in the core 103B. Each of the winding turns 812A and 812B is configured to carry half a turn of the primary winding 812 for each transformer cell 100, with the winding turns 812A and 812B configured to complete one full turn for the matrix transformer 810 when connected in series. The reduced twisting with the semi-serpentine windings also helps to reduce the primary winding loss, and hence improve the efficiency of the matrix transformer 810.

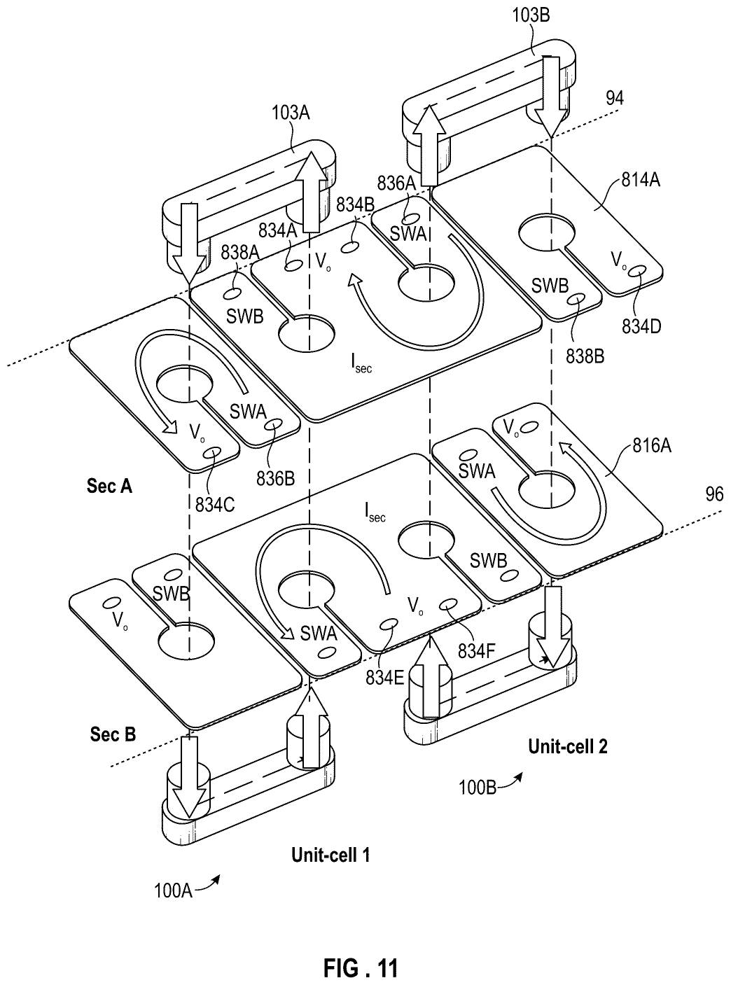

FIG. 11 depicts a perspective view of the first secondary winding 814 and the second secondary winding 816 according to one or more embodiments of the present disclosure. As discussed above, the first secondary winding 814 and the second secondary winding 816 can each include multiple winding turns with each winding turn implemented in a separate secondary layer among the plurality of layers 300. For example, the first secondary winding 814 includes a first winding turn 814A, and the second secondary winding 816 includes a first winding turn 816A. The winding turn 814A can be implemented in the intermediate layers 352 or 362, and the winding turn 816A can be implemented in the intermediate layer 356 or 358, for example. The secondary windings 814 and 816 can be configured to provide an output current and voltage to output capacitors 121A, 122A, 221A, 222A, 121B, 122B, 221B, and/or 222B.

As discussed above, each secondary winding of the secondary windings 814 and 816 includes merged output voltage nodes. The merged output voltage nodes result from the merging of the secondary windings 814 and 816, which is enabled from the structure of the primary winding 812 that implements the semi-serpentine current flow. The semi-serpentine current flow causes the flux direction in adjacent cores to be inverted, which results in the output voltage nodes of the secondary windings 814 and 816 to align next to each other between the transformer cells 100A, 100B, etc. For example, the winding turn 814A includes output voltage nodes 834A and 834B which have been merged between the first transformer cell 100A and 100B. The merged output voltage nodes 834A and 834B, for electrical connection to the output capacitors 122A and 121B for example, enables a greater area for secondary current to flow through the first secondary winding 814. The merged output voltage nodes 834A and 834B are located centrally away from the cores 103A and 103B in a first direction toward a first edge 94 of the first secondary winding 814. The winding turn 814A includes other output voltage nodes 834C and 834D peripherally away from the cores 103A and 103B in a second direction toward an opposite edge to the first edge 94. These can further be merged with the corresponding output voltage nodes of additional unit-cells, when available. The winding turn 814A also includes switching nodes 836A, 836B, 838A, and 838B. The winding turn 814A includes multiple air gaps between various switching nodes 836A, 836B, 838A, and 838B and output voltage nodes 834A, 834B, 834C, and 834D as depicted.

The second secondary winding 816 and the first secondary winding 814 are sequentially stacked and symmetrically aligned but in reverse or mirror configuration. As such, the winding turn 816A includes the same switching nodes and output voltage nodes as those of the winding turn 814A but in a reverse or mirror configuration. For example, the winding turn 816A includes output voltage nodes 834E and 834F which have been merged between the first transformer cell 100A and 100B. The output voltage nodes 834E and 834F are located centrally away from the cores 103A and 103B in a second direction opposite the first direction toward a first edge 96 of the second secondary winding 816. The merged output voltage nodes 834E and 834F, for electrical connection to the output capacitors 122A and 121B for example, enables a greater area for secondary current to flow through the second secondary winding 816.

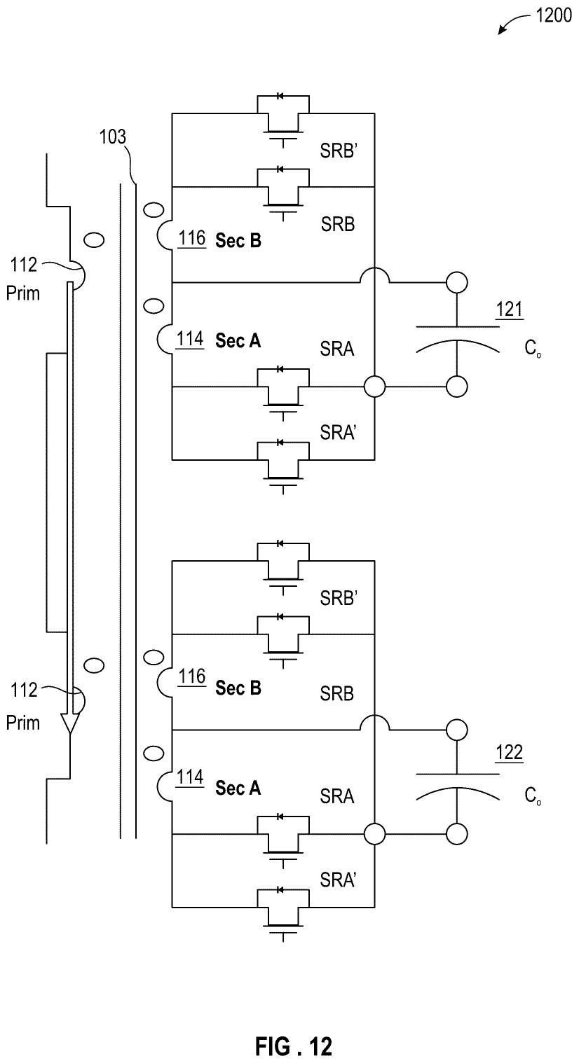

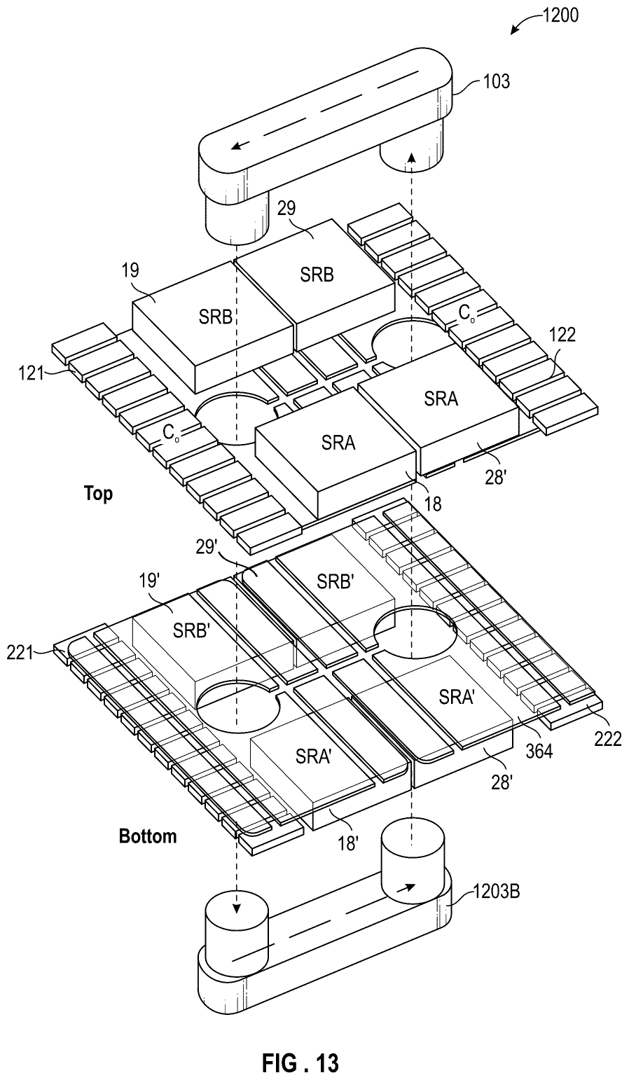

FIG. 12 depicts a circuit schematic of a transformer cell 1200 including center-tap rectifiers with parallel switching devices, and FIG. 13 depicts a perspective view of the transformer cell 1200, according to one or more embodiments of the present disclosure. The transformer cell 1200 is similar in configuration to the transformer cell 100 but includes center-tap rectifiers connected in parallel. For example, the transformer cell 1200 includes identical switching devices located at or below the bottom layer 364 for parallel connection to the switching devices 18, 19, 28, and 29 located at or above the top layer 350. Particularly switching device 19′ can be electrically connected in parallel with the switching device 19, switching device 29′ can be electrically connected in parallel with the switching device 29, switching device 18′ can be electrically connected in parallel with the switching device 18, and switching device 28′ can be electrically connected in parallel with the switching device 28. Multiple transformer cells 1200 can be employed in the matrix transformer 810 for use in power conversion applications.

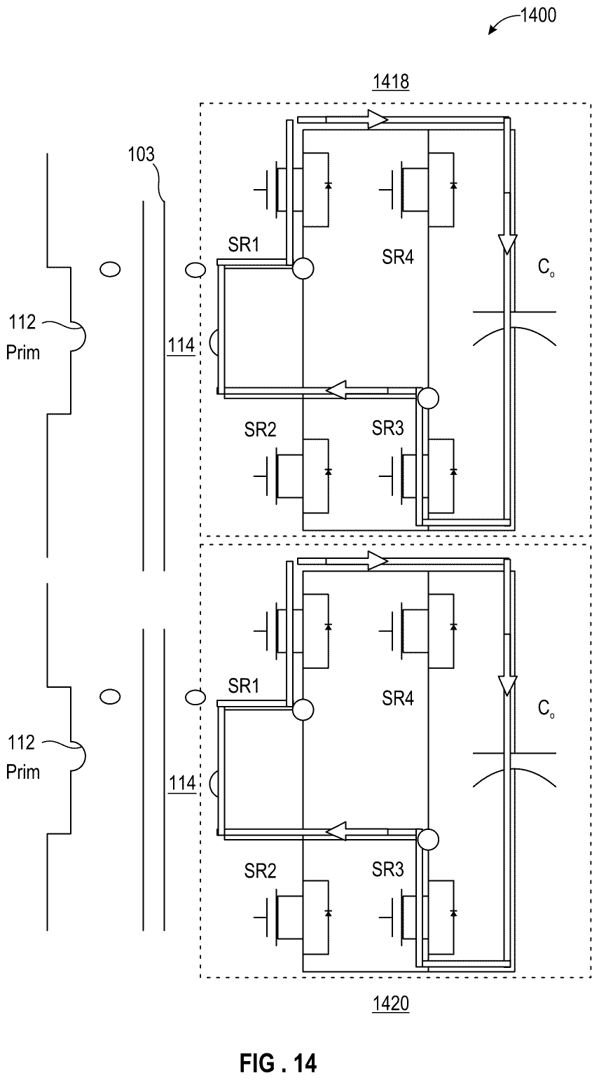

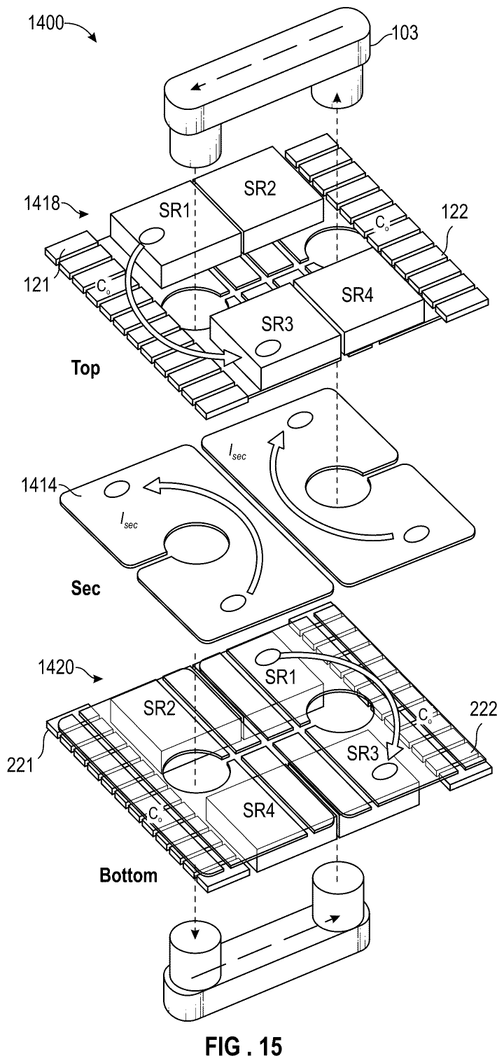

FIG. 14 depicts a circuit schematic of a transformer cell 1400 including full-bridge rectifiers, and FIG. 15 depicts a perspective view of the transformer cell 1400, according to one or more embodiments of the present disclosure. The transformer cell 1400 is similar in configuration to the transformer cell 100 and the transformer cell 1200 (e.g., includes identical SRs) but includes a full-bridge rectifier system. For example, the transformer cell 1400 includes a first half-bridge rectifier system 1418 electrically connected to a second half-bridge rectifier system 1420 via the first secondary winding 114 and/or the second secondary winding 116. Multiple transformer cells 1400 can be employed in the matrix transformer 810 for use in power conversion applications.

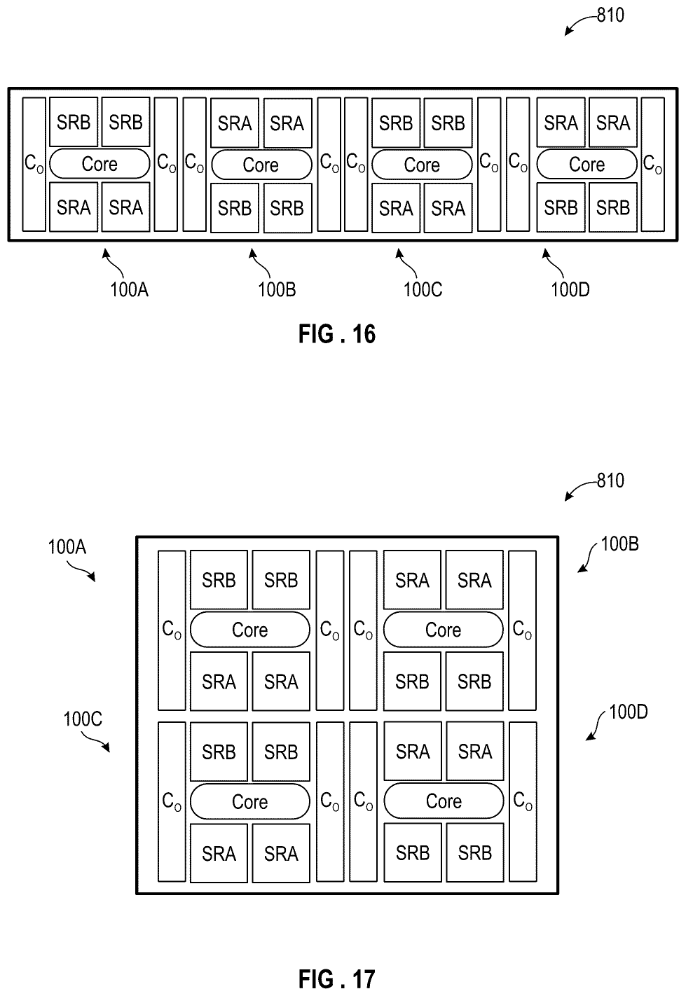

FIG. 16 depicts a cell arrangement of the matrix transformer 810 according to one or more embodiments of the present disclosure. For example, the matrix transformer 810 depicted in FIG. 16 integrates four transformer cells 100 (e.g., transformer cells 100A, 100B, 100C, and 100D) arranged in a row. As discussed above, the matrix transformer 810 can integrate more or fewer than four transformer cells 100 depending on the step-down ratio and IBV voltage required or desired for a second stage VR system or for a load.

FIG. 17 depicts a cell array arrangement of the matrix transformer 810 according to one or more embodiments of the present disclosure. For example, the matrix transformer 810 depicted in FIG. 17 integrates four transformer cells 100 (e.g., transformer cells 100A, 100B, 100C, and 100D) in a 2×2 cell array. As discussed, above the matrix transformer 810 can integrate more or fewer than four transformer cells 100 in a cell array depending on the step-down ratio and IBV voltage required or desired for a second stage VR system or for a load. For a cell array, winding turns of the primary winding 812 and the secondary windings 814 and 816 can be expanded in each layer of a PCB stack based on the number of columns in the cell array. For example, for a 2×2 cell array, the primary winding 812 can include two of the winding turns 812A in a same layer among the plurality of layers, where the two winding turns 812A are physically merged symmetrically but in a mirror or reverse configuration.

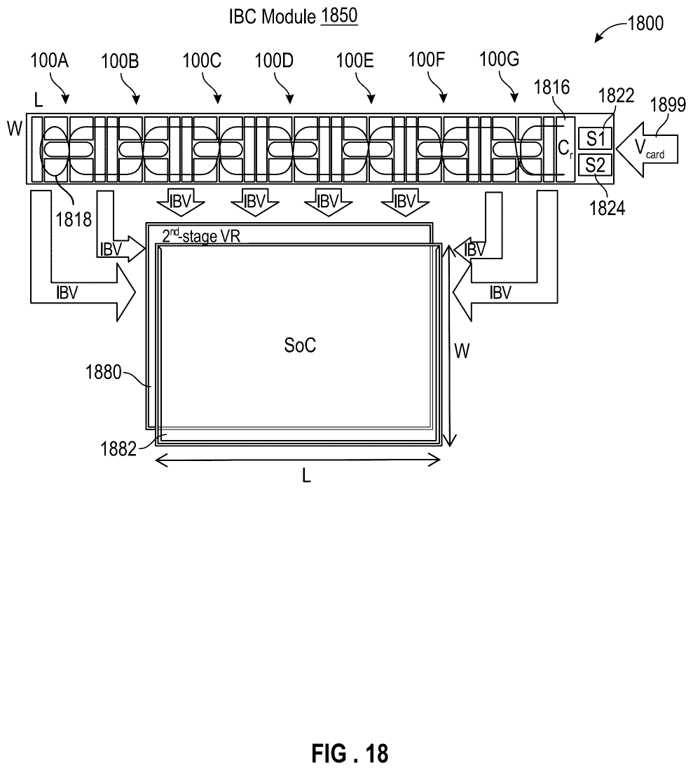

FIG. 18 depicts a schematic of an example two-stage power delivery system 1800 according to one or more embodiments of the present disclosure. The two-stage power delivery system 1800 includes a system on chip (SoC) 1882, a second stage VR system 1880 configured to be electrically connected to the SoC 1882, and an IBC module 1850 configured to be electrically connected to the second stage VR system 1880. As discussed previously, the SoC 1882 can include CPUs, GPUs, and/or memory devices, among others. The two-stage power delivery system 1800 can correspond to a VPD architecture where the second stage VR system 1880 is positioned underneath the SoC 1882, and the IBC module 1850 is positioned above the second stage VR system 1880 and near the SoC 1882 (e.g., on a SoC card housing the SoC 1882). The IBC module 1850 includes a resonant capacitor 1816, a first primary switching device 1822, and a second primary switching device 1824. The IBC module 1850 also includes a matrix transformer (e.g., the matrix transformer 810) that includes one or more transformer cells 100A, 100B, 100C, 100D, 100E, 100F, and 100G connected in series with one another, a first primary switching device 1812, a second primary switching device 1814, and a resonant capacitor 1816. As illustrated, the IBC module 1850 includes seven transformer cells that are connected in series by a primary winding 1818. The primary winding 1818 is similar to the primary winding 812 and the description regarding the primary winding 812 is applicable to the primary winding 1818. For example, the primary winding 1818 implements a winding structure that enables a semi-serpentine current flow.

The IBC module 1850 is a resonant converter-based IBC configured to generate an IBV based on a voltage received from a DC power source 1899 and transmit the IBV to the second stage VR system 1880. For low IBV requirements, a larger number of the transformer cells 100 can be required to attain the required turns ratio, and the transformer cells 100 can be implemented into a single IBC module such as the IBC module 1850. However, such implementation can result in the IBC module (e.g., the IBC module 1850) being longer in length than the SoC 1882 as depicted, which can cause asymmetrical PDN resistance from each of the transformer cells 100A, 100B, 100C, etc. to the second stage VR system 1880, leading to current-sharing issues and large PDN loss.

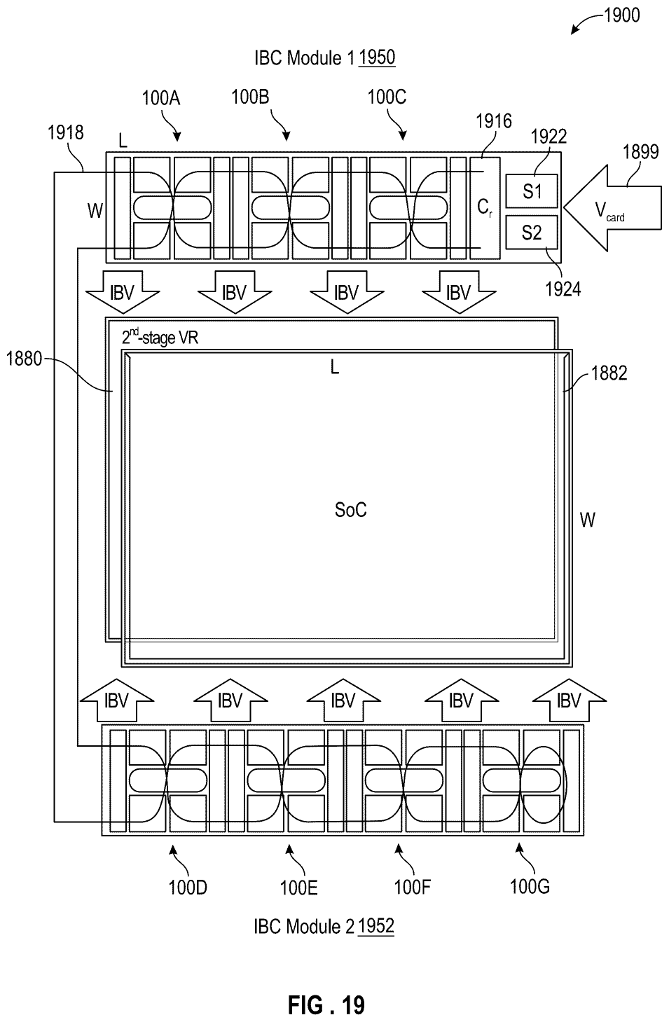

FIG. 19 depicts a schematic of an example two-stage power delivery system 1900 that improves upon various features of the two-stage power delivery system 1800, according to one or more embodiments of the present disclosure. The two-stage power delivery system 1900 can correspond to a VPD architecture and includes similar components to the two-stage power delivery system 1800 such as the SoC 1882, the second stage VR system 1880, and the DC power source 1899. However, the two-stage power delivery system 1900 includes a first IBC module 1950 and a second IBC module 1952, which are placed around and near the SoC 1882, instead of a single IBC module such as the IBC module 1850. In contrast to the two-stage power delivery system 1800, a single IBC module is split into two smaller IBC modules (e.g., the IBC module 1950 and the IBC module 1952) for the two-stage power delivery system 1900. For example, a single IBC module, such as the IBC module 1850, can be split into the IBC module 1950 and the IBC module 1952 and be placed near opposite ends of the SoC 1882 in a substantially symmetrical fashion as depicted. The IBC module 1950 and the IBC module 1952 can be substantially similar in length and do not exceed the length (L) of the SOC 1882. Additionally, the IBC modules 1950 and 1952 can be placed above the second stage VR system 1880 on a SoC card housing the SoC 1882.

The first IBC module 1950 is similar to the IBC module 1850 in that the IBC module 1950 includes a matrix transformer (e.g., the matrix transformer 810) including three transformer cells 100A, 100B, and 100C, and includes a first primary switching device 1922, a second primary switching device 1924, and a resonant capacitor 1916. The second IBC module 1952 also includes a matrix transformer (e.g., the matrix transformer 810) including four transformer cells 100D, 100E, 100F, and 100G. Each transformer cell 100 in the IBC modules 1950 and 1952 can be connected in series via a primary winding 1918. The primary winding 1918 is similar to the primary winding 1818 and the description regarding the primary winding 1818 is applicable to the primary winding 1918. The inclusion of two separate IBC modules 1950 and 1952 enables the two-stage power delivery system 1900 to provide a symmetrical and low PDN resistance path from each unit cell 100 to the second stage VR system 1880.

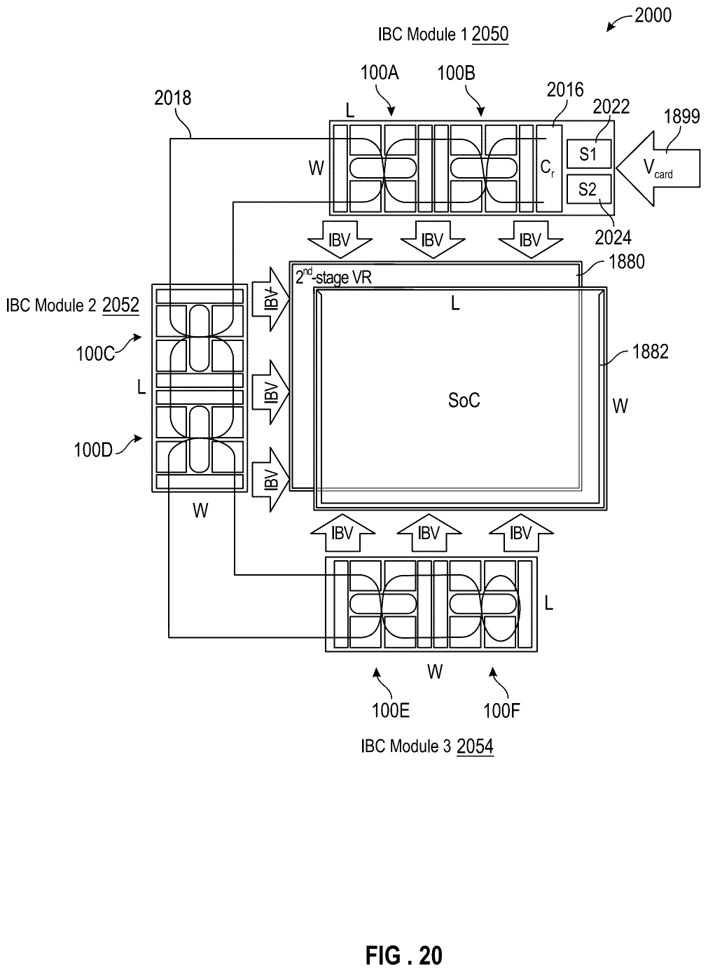

FIG. 20 depicts a schematic of an example two-stage power delivery system 2000 that improves upon various features of the example two-stage power delivery system 1800, according to one or more embodiments of the present disclosure. The two-stage power delivery system 2000 can correspond to a VPD architecture and includes similar components to the two-stage power delivery system 1800 such as the SoC 1882, the second stage VR system 1880, and the DC power source 1899. However, the two-stage power delivery system 2000 includes a first IBC module 2050, a second IBC module 2052, and a third IBC module 2054, which are placed near and around the SoC 1882, instead of a single IBC module such as the IBC module 1850. In contrast to the two-stage power delivery system 1800, a single IBC module is split into three smaller IBC modules (e.g., the IBC modules 2050, 2052, and 2054) for the two-stage power delivery system 2000. The first IBC module 2050 and the third IBC module 2054 are placed near opposite ends of the SoC 1882 in a substantially symmetrical fashion as depicted. The second IBC module 2052 is placed near a different end (e.g., transverse end compared to the ends that the first and the second IBC modules 2050 and 2054 are placed near) of the SoC 1882. It should be noted that the length of the first IBC module 2050 and the length of the third IBC module 2054 do not exceed the length (L) of the SoC 1882 as depicted. Additionally, the length of the second IBC module 2052 does not exceed the width (W) of the SoC 1882. Additionally, the IBC modules 2050, 2052, and 2054 can be placed above the second stage VR system 1880 on a SoC card housing the SoC 1882.

The first IBC module 2050 is similar to the IBC module 1850 in that the IBC module 2050 includes a matrix transformer (e.g., the matrix transformer 810) including two transformer cells 100A and 100B, and includes a first primary switching device 2022, a second primary switching device 2024, and a resonant capacitor 2016. The second IBC module 2052 also includes a matrix transformer (e.g., the matrix transformer 810) including two transformer cells 100C and 100D. The third IBC module 2054 also includes a matrix transformer (e.g., the matrix transformer 810) including two transformer cells 100E and 100F. Each transformer cell 100 in the IBC modules 2050, 2052, and 2054 can be connected in series via a primary winding 2018. The primary winding 2018 is similar to each of the primary windings 1818 and 1918, and the description regarding each of the primary windings 1818 and 1918 is applicable to the primary winding 2018. The inclusion of three separate IBC modules 2050, 2052, and 2054 enables the two-stage power delivery system 2000 to provide a symmetrical and low PDN resistance path from each unit cell 100 to the second stage VR system 1880.

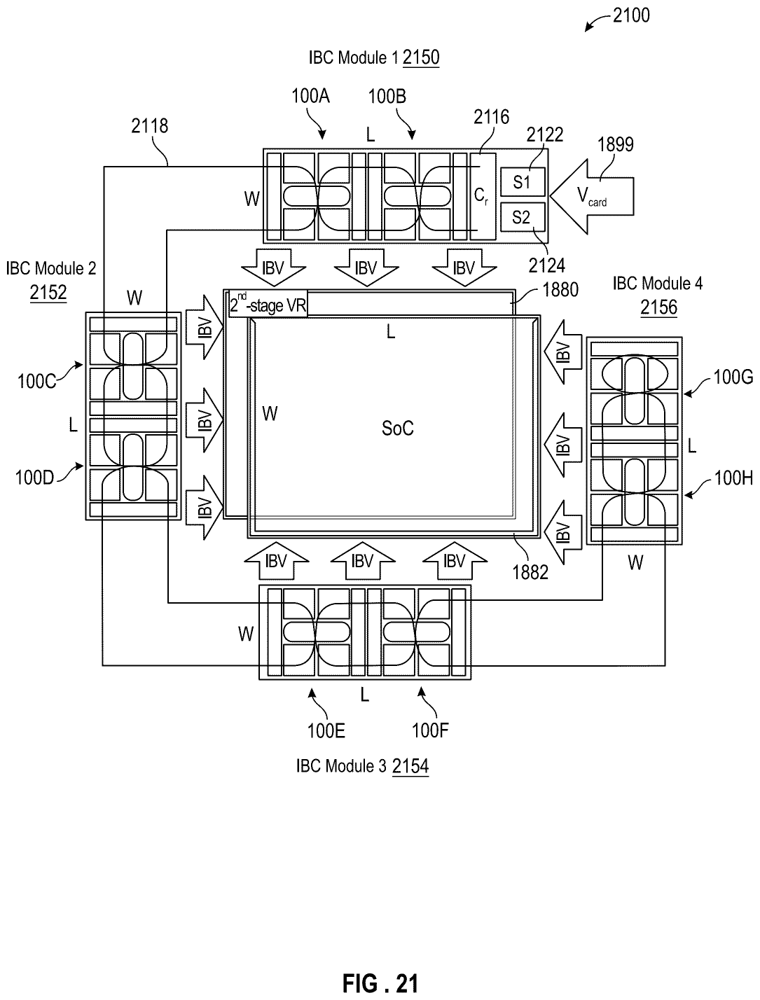

FIG. 21 depicts a schematic of an example two-stage power delivery system 2100 that improves upon various features of the example two-stage power delivery system 1800, according to one or more embodiments of the present disclosure. The two-stage power delivery system 2100 can correspond to a VPD architecture and includes similar components to the two-stage power delivery system 1800 such as the SoC 1882, the second stage VR system 1880, and the DC power source 1899. However, the two-stage power delivery system 2100 includes a first IBC module 2150, a second IBC module 2152, a third IBC module 2154, and a fourth IBC module 2156, which are placed near and around the SoC 1882, instead of a single IBC module such as the IBC module 1850. In contrast to the two-stage power delivery system 1800, a single IBC module is split into four smaller IBC modules (e.g., the IBC modules 2150, 2152, 2154, and 2056) for the two-stage power delivery system 2100. The first IBC module 2150 and the third IBC module 2154 are placed near opposite ends of the SoC 1882 in a substantially symmetrical fashion as depicted. The second IBC module 2152 and the fourth IBC module 2156 are also placed near opposite ends (e.g., near ends that are transverse to the opposite ends that the first and the third IBC modules 2150 and 2154 are placed near) of the SoC 1882 in a substantially symmetrical fashion as depicted. It should be noted that the length of the first IBC module 2150 and the length of the third IBC module 2154 do not exceed the length (L) of the SoC 1882 as depicted. Additionally, the length of the second IBC module 2152 and the length of the fourth IBC module 2156 do not exceed the width (W) of the SoC 1882 as depicted. Additionally, the IBC modules 2150, 2152, 2154, and 2156 can be placed above the second stage VR system 1880 on a SoC card housing the SoC 1882.

The first IBC module 2150 is similar to the IBC module 1850 in that the IBC module 2150 includes a matrix transformer (e.g., the matrix transformer 810) including two transformer cells 100A and 100B, and includes a first primary switching device 2122, a second primary switching device 2124, and a resonant capacitor 2116. The IBC modules 2152, 2154, and 2156 also each includes a matrix transformer (e.g., the matrix transformer 810) including two transformer cells 100C and 100D, 100E and 100F, and 100G and 100H, respectively. Each transformer cell 100 in the IBC modules 2150, 2152, 2154, 2156 can be connected in series via a primary winding 2118. The primary winding 2118 is similar to each of the primary windings 1818, 1918, and 2018, and the description regarding each of the primary windings 1818, 1918, and 2018 is applicable to the primary winding 2118. The inclusion of four separate IBC modules 2150, 2152, 2154, 2156 enables the two-stage power delivery system 2100 to provide a symmetrical and low PDN resistance path from each unit cell 100 to the second stage VR system 1880.

It should be noted that the transformer cell configuration in the above-described IBC modules for FIGS. 18-21 is not limited thereto. For example, an IBC module may include greater or fewer than the number of transformer cells that are described depending on available space near the SoC 1882, the total power requirements of the SoC 1882, and the power rating of each transformer cell 100.

The features, structures, or characteristics described above may be combined in one or more embodiments in any suitable manner, and the features discussed in the various embodiments are interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims. If a component is described as having “one or more” of the component, it is understood that the component can be referred to as “at least one” component.

The terms “first,” “second,” etc. are used only as labels, rather than a limitation for a number of the objects. It is understood that if multiple components are shown, the components may be referred to as a “first” component, a “second” component, and so forth, to the extent applicable.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X; Y; Z; X or Y; X or Z; Y or Z; X, Y, or Z; etc.). Thus, such disjunctive language is not generally intended to, and should not, imply that certain embodiments require at least one of X, at least one of Y, or at least one of Z to each be present.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Therefore, at least the following is claimed:

1. A transformer cell, comprising:
a printed circuit board (PCB) comprising a plurality of layers;
at least two transformers, comprising:
a primary winding implemented in a plurality of primary layers among the plurality of layers;
a plurality of secondary windings implemented in a plurality of secondary layers among the plurality of layers; and
a core extending through the primary winding and the plurality of secondary windings;
a first output capacitor electrically connected to the plurality of secondary windings and located above a top layer among the plurality of layers and along a first edge of the PCB;
a second output capacitor electrically connected to the plurality of secondary windings and located above the top layer and along a second edge of the PCB, the second edge being opposite the first edge; and
one or more switching devices electrically connected to the first output capacitor and the second output capacitor, the one or more switching devices located between the first output capacitor and the second output capacitor.

2. The transformer cell of claim 1, wherein the primary winding and the plurality of secondary windings are planar PCB windings.

3. The transformer cell of claim 1, wherein the plurality of layers comprises a bottom layer, the transformer cell further comprising:
a third output capacitor electrically connected to the plurality of secondary windings and located below the bottom layer and along the first edge of the PCB, wherein the first output capacitor and the third output capacitor are symmetrically aligned; and
a fourth output capacitor electrically connected to the plurality of secondary windings and located below the bottom layer and along the second edge of the PCB, wherein the second output capacitor and the fourth output capacitor are symmetrically aligned.

4. The transformer cell of claim 1, wherein the plurality of secondary windings comprises a first secondary winding and a second secondary winding, the first secondary winding and the second secondary winding each comprising a plurality of winding turns and each winding turn among the plurality of winding turns corresponding to a different layer among the plurality of layers.

5. The transformer cell of claim 4, wherein for a winding turn among the plurality of winding turns of the first secondary winding, the winding turn comprises:
a first switching node and a second switching node, the first switching node and the second switching node configured to be electrically connected to the one or more switching devices, wherein:
the first switching node and the second switching node are located centrally away from the core in a first direction and substantially at a first edge of the winding turn; and
the first switching node and the second switching node are separated by an air gap.

6. The transformer cell of claim 5, wherein the winding turn further comprises a first output voltage node and a second output voltage node, the first output voltage node configured to be electrically connected to the one or more first output capacitors and the second output voltage node configured to be electrically connected to the second output capacitor, wherein:
the first output voltage node and the second output voltage node are located away from the core in the first direction;
the first output voltage node is separated from the first switching node by an air gap;
the second output voltage node is separated from the second switching node by an air gap; and
the first switching node and the second switching node are positioned between the first output voltage node and the second output voltage node.

7. The transformer cell of claim 5, wherein:
the one or more switching devices comprises a first set of switching devices configured to be electrically connected to the first secondary winding, the first set of switching devices comprising a first switching device and a second switching device, the first switching device configured to be electrically connected to the first switching node, and the second switching device configured to be electrically connected to the second switching node;
the first switching device is positioned directly above a first switching area defined by an area enclosing the first switching node; and
the second switching device is positioned directly above a second switching area defined by an area enclosing the second switching node.

8. The transformer cell of claim 7, wherein:
the first output capacitor extends along a second edge of the winding turn of the first secondary winding, the second edge being transverse to the first edge; and
the second output capacitor extends along a third edge of the winding turn, the third edge being transverse to the first edge and opposite the second edge.

9. The transformer cell of claim 8, wherein for a winding turn among the plurality of winding turns of the second secondary winding, the winding turn comprises:
a first switching node and a second switching node, the first switching node and the second switching node configured to be electrically connected to the one or more switching devices, wherein:
the first switching node and the second switching node are located centrally away from the core in a second direction opposite the first direction and substantially at a first edge of the winding turn; and
the first switching node and the second switching node are separated by an air gap.

10. The transformer cell of claim 9, wherein the winding turn further comprises a first output voltage node and a second output voltage node, the first output voltage node configured to be electrically connected to the first output capacitor and the second output voltage node configured to be electrically connected to the second output capacitor, wherein:
the first output voltage node and the second output voltage node are located away from the core in the second direction;
the first output voltage node is separated from the first switching node by an air gap;
the second output voltage node is separated from the second switching node by an air gap; and
the first switching node and the second switching node are positioned between the first output voltage node and the second output voltage node.

11. The transformer cell of claim 10, wherein:
the one or more switching devices comprises a second set of switching devices configured to be electrically connected to the second secondary winding, the second set of switching devices comprising a first switching device and a second switching device, the first switching device configured to be electrically connected to the first switching node, and the second switching device configured to be electrically connected to the second switching node;
the first switching device is positioned directly above a first switching area defined by an area enclosing the first switching node; and
the second switching device is positioned directly above a second switching area defined by an area enclosing the second switching node.

12. The transformer cell of claim 11, wherein:
the first set of switching devices is positioned away from the core in the first direction; and
the second set of switching devices is positioned away from the core in the second direction.

13. A matrix transformer, comprising:
a printed circuit board (PCB) comprising a plurality of layers;
a plurality of transformer cells comprising at least a first transformer cell electrically connected with a second transformer cell, the plurality of transformer cells comprising:
a primary winding located implemented in a plurality of primary layers among the plurality of layers;
a plurality of secondary windings implemented in a plurality of secondary layers among the plurality of layers;
a plurality of cores extending through the primary winding and the plurality of secondary windings;
a first output capacitor electrically connected to the plurality of secondary windings and located above a top layer among the plurality of layers and along a first edge of the PCB;
a second output capacitor electrically connected to the plurality of secondary windings and located above the top layer among the plurality of layers and along a second edge of the PCB, the second edge being opposite the first edge; and
one or more switching devices electrically connected to the first output capacitor and the second output capacitor, the one or more switching devices located between the first output capacitor and the second output capacitor.

14. The matrix transformer of claim 13, wherein the primary winding is configured to generate a current having a semi-serpentine current flow, a direction of the semi-serpentine current flow defined by a plurality of air gaps structurally integrated in the primary winding.

15. The matrix transformer of claim 14, wherein:
the plurality of air gaps comprises a plurality of outer air gaps and a plurality of central air gaps located between the plurality of cores;
the plurality of central air gaps extends toward a first edge of the primary winding; and
the plurality of outer air gaps extends toward a second edge of the primary winding, the first edge being opposite the second edge.

16. The matrix transformer of claim 13, wherein:
the plurality of cores comprises a first core and a second core; and
a magnetic flux direction guided by the first core is inverted from a magnetic flux direction guided by the second core.

17. The matrix transformer of claim 13, wherein the plurality of secondary windings comprises a first secondary winding and a second secondary winding, the first secondary winding and the second secondary winding each comprising a plurality of winding turns and each winding turn among the plurality of winding turns corresponding to a different layer among the plurality of layers.

18. The matrix transformer of claim 17, wherein for a winding turn among the plurality of winding turns of the first secondary winding, the winding turn comprises:
a merged output voltage node between the first transformer cell and the second transformer cell, the merged output voltage node located centrally away from the plurality of cores in a first direction toward a first edge of the first secondary winding, and
wherein for a winding turn among the plurality of winding turns of the second secondary winding, the winding turn comprises:
a merged output voltage node between the first transformer cell and the second transformer cell, the merged output voltage node located centrally away from the plurality of cores in a second direction toward a first edge of the second secondary winding, the second direction opposite the first direction.

19. The matrix transformer of claim 13, wherein:
the one or more switching devices are secondary rectifiers configured as center-tap (CT) rectifiers or full-bridge (FB) rectifiers; and/or
the one or more switching devices are positioned at or above the top layer; and/or
the one or more switching devices are positioned at or below a bottom layer among the plurality of layers.

20. The matrix transformer of claim 13, wherein the matrix transformer is implemented as a first stage intermediate bus converter (IBC) in a two-stage power delivery system, the two-stage power delivery system including a second stage voltage regulator (VR) system and a load, wherein:
the first-stage IBC is implemented as a plurality of IBC modules, the plurality of IBC modules positioned symmetrically near the load;
the plurality of IBC modules is configured to symmetrically provide an intermediate bus voltage (IBV) to the second stage VR system; and
the second stage VR system is configured to provide an output voltage to the load based on the IBV.
